(19) United States
(12) Patent Application Publication
(10) Pub. No.: US 2010/0019256 A1
(43) Pub. Date: Jan. 28, 2010

(54) LIGHT EMITTING DEVICE WITH ELECTRON BLOCKING COMBINATION LAYER

(75) Inventors: PENG YI WU, TAICHUNG CITY (TW); SHIH CHENG HUANG, HSINCHU CITY (TW); PO MIN TU, CHIAYI COUNTY (TW); YING CHAO YEH, TAIPEI COUNTY (TW); WEN YU LIN, TAICHUNG COUNTY (TW); CHIH PENG HSU, TAINAN COUNTY (TW); SHIH HSIUNG CHAN, HSINCHU COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED OPTOELECTRONIC TECHNOLOGY INC., HSINCHU COUNTY (TW)

(21) Appl. No.: 12/506,688

(22) Filed: Jul. 21, 2009

(30) Foreign Application Priority Data
Jul. 24, 2008 (TW) 097128065

(51) Int. Cl. H01L 33/00

(52) U.S. Cl. 257/94; 257/E33.023

(57) ABSTRACT

A light emitting device with an electron blocking combination layer comprises an active layer, an n-type GaN layer, a p-type GaN layer, and an electron blocking combination layer which has two Group III-V semiconductor layers with different band gaps that can be deposited periodically and repeatedly on the active layer to block overflowing electrons from the active layers.

### BACKGROUND OF THE INVENTION

(A) Field of the Invention

The present invention relates to an electrical product, and more particularly, to a light emitting device.

(B) Description of the Related Art

In the functioning of a light emitting device, the phenomenon of electron overflow not only reduces the lighting efficiency of a device, but also increases the temperature so that the working life of the device is affected. Therefore, it is very important for manufacturing the light emitting device to effectively reduce electron overflow.

FIG. 1 is a schematic cross-sectional diagram of a conventional light emitting device made of GaN group semiconductor. As shown in FIG. 1, the conventional light emitting device comprises an n-type GaN layer 102, an active layer 112, and a p-type GaN layer 122.

FIG. 2 is schematic energy diagram of each of several band gaps in accordance with FIG. 1. The upper portion of FIG. 2 shows the energy of an electron path, and the lower portion of FIG. 2 shows the energy of a hole path. Generally, the mobility of an electron is larger than that of a hole, and the concentration of electrons is also larger than that of holes. Therefore, there are excessive electrons (e, the upper portion of FIG. 2) overflowing the active layer 112 where it is close to the p-type GaN layer 122. The occurrence of the electron overflow reduces the possibility of radiation recombination.

U.S. Pat. No. 7,067,838 and U.S. Pat. No. 7,058,105 respectively provide a light emitting device employing GaN group semiconductor. These light emitting devices comprise a barrier layer in which the energy of the band gap is larger than those of the other layers so as to reduce the electron overflow. It is worth noticing that all of these prior arts use AlGaN as a barrier layer. Because of the lattice mismatch of AlGaN and GaN, the content of Al needs to be increased so as to have a sufficient energy barrier for blocking electron overflow. However, when the content of Al is increased, the light emitting device accordingly suffers increased stress. If the thickness of the layer is larger than a certain critical thickness, the stress would be released to crack the device. Furthermore, as the content of Al is increased, the quality of crystal lattices degrades, and accordingly, the concentration of holes of AlGaN is difficult to increase.

Therefore, a light emitting device is provided to reduce the occurrence of electron overflow and also to avoid the disadvantages of the aforesaid stress release.

### SUMMARY OF THE INVENTION

The present invention provides a light emitting device with an electron blocking combination layer, which comprises an active layer, an n-type GaN layer and a p-type GaN layer. The light emitting device with an electron blocking combination layer further comprises a first Group III-V semiconductor layer and a second Group III-V semiconductor layer. The two kinds of Group III-V semiconductor layers have different band gaps, and are periodically and repeatedly deposited on the active layer to form an electron blocking combination layer with higher energy barrier so as to block excessive electrons from overflowing the active layer.

One of advantages is that the electron blocking combination layer can prevent electron overflow so that the possibility of the recombination of electrons and holes within the active layer is increased and photons are accordingly released. Furthermore, the combination of Group III-V semiconductor layers with various crystal lattice constants has the effect of stress compensation so that the accumulated stress between it and the active layer is reduced.

### BRIEF DESCRIPTION OF THE DRAWINGS

The objectives and advantages of the present invention will become apparent upon reading the following description and upon reference to the accompanying drawings in which:

FIG. 1 is a schematic cross-sectional diagram of a conventional light emitting device made of GaN group semiconductor;

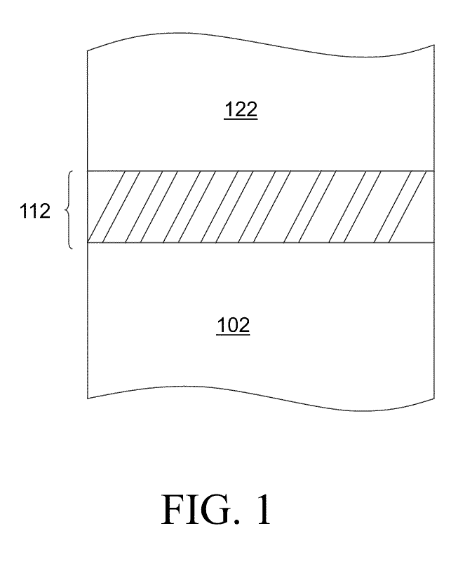

FIG. 2 is schematic energy diagram of each of band gaps in accordance with FIG. 1;

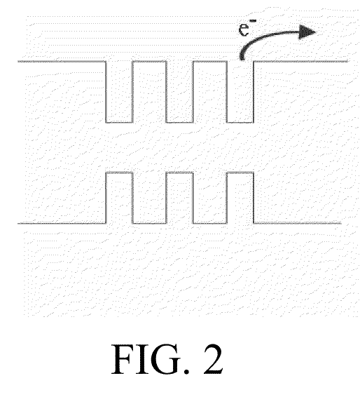

FIG. 3 is a cross-sectional diagram of a light emitting device with an electron blocking combination layer in accordance with the present invention; and

FIG. 4 is schematic energy diagram of each of several band gaps in accordance with FIG. 3.

### DETAILED DESCRIPTION OF THE INVENTION

One aspect of the present invention proposes a light emitting device with an electron blocking combination layer. In order to provide a thorough understanding of the present invention, a detailed description of a number of method steps and components is provided below. The practice of the present invention is not limited to any specific detail of a light emitting device that is familiar to one skilled in the art. On the other hand, components or method steps which are well-known are not described in detail in order to avoid unnecessary limitations. A preferred embodiment of the present invention will be described in detail. However, in addition to the preferred embodiment described, other embodiments can be broadly employed, and the scope of the present invention is not limited by any of the embodiments, but should be defined in accordance with the following claims and their equivalent.

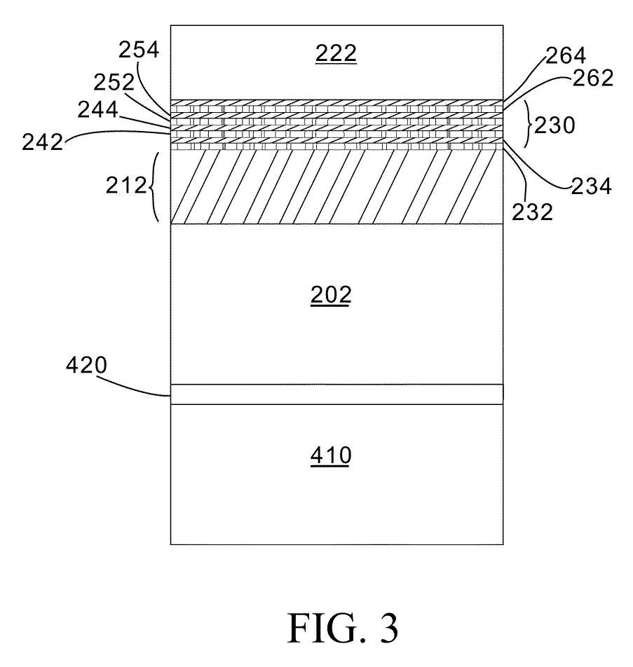

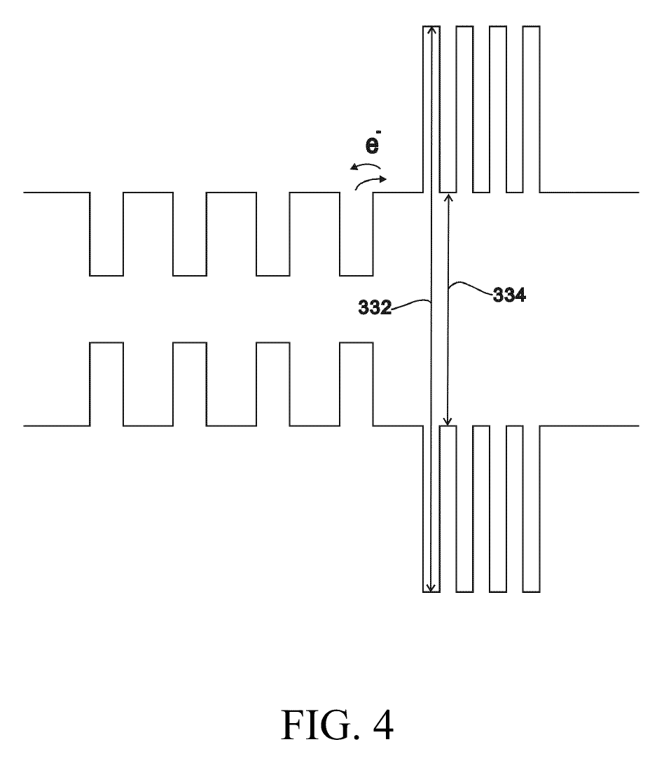

FIG. 3 is a cross-sectional diagram of a light emitting device with an electron blocking combination layer in accordance with the present invention. FIG. 4 is schematic energy diagram of each of several band gaps in accordance with FIG. 3. Referring FIG. 3 and FIG. 4, a light emitting device with an electron blocking combination layer comprises a substrate 410, a buffer layer 420 on the substrate 410, an n-type GaN layer 202 on the buffer layer 420, an active layer 212 and a p-type GaN layer 222. There is a plurality of electrons within the active layer 212. FIG. 4 shows an electron (e⁻) as an example.

The material of the aforesaid substrate can be Al₂O₃ (sapphire), SiC, Si, GaN, AIN, LiAlO₂, LiGaO₂, or ZnO.

The aforesaid light emitting device with an electron blocking combination layer can further comprise first Group III-V semiconductor layers 232, 242 and second Group III-V semiconductor layers 234, 244. The two kinds of Group III-V semiconductor layers have different band gaps, and are periodically and repeatedly deposited on the active layer 212 to form an electron blocking combination layer 230 with higher energy barrier (higher than the energy barrier of the active layer) so as to block excessive electrons (e⁻) from overflowing the active layer 212.

Referring FIG. 4, the electron blocking combination layer 230 is interposed between the p-type GaN layer 222 and the active layer 212. When the electrons (e⁻) meet the electron blocking combination layer 230 with a higher energy barrier, the electron blocking combination layer 230 acts as a wall to rebound the electrons (e⁻) into the quantum wells of the active layer 212. The electrons (e⁻) are recombined with holes so that photons are released. Therefore, the electron blocking combination layer 230 can increase the recombination rate of the electrons and the holes so as to avoid the phenomenon of electron overflow.

It is worth noting that the combination of two Group III-V semiconductor layers 232, 234 with different crystal lattice constants has the effect of stress compensation so that the stress between the semiconductor layers and the active layer is reduced.

The aforesaid electron barrier 230 can also be deemed as a combination epitaxy structure 230. The combination epitaxy structure 230 comprises the combination of a first AlInGaN (AlₓIn_{y}Ga_{1-x-y}N) layer 232 and a second AlInGaN (AlᵤInᵥGa₁₋ᵤ₋ᵥN) layer 234, where 0<x≦1, 0≦y<1, x+y≦1, 0≦u<1, 0≦v≦1, and u+v≦1. The combined layers can be repeatedly deposited. When x=u, y≠v. The electron blocking combination layer 230 can effectively increase the concentration of holes.

Referring to FIG. 3, the first AlInGaN layer 232 has a first thickness, and the second AlInGaN layer 234 has a second thickness, wherein the first AlInGaN layer 232 is below the second AlInGaN layer 234 with bigger band gaps 332 (see FIG. 4), and the second AlInGaN layer 234 is above the first AlInGaN layer 232 with smaller band gaps 332 (see FIG. 4). The differences between the two kinds of AlInGaN layers 232, 234 are the proportions of N, Ga, In, and Al. One of the objectives of varying the proportions is make the band gap 332 of the first AlInGaN layer 232 be higher than the band gap 334 of the second AlInGaN layer 234. In general, the proportion of the Al element is increased to make the band gap accordingly higher; and the proportion of the In element is increased to make the band gap accordingly lower.

The In element is important for the first AlInGaN layer 232 and the second AlInGaN layer 234. That is, if there is no In element therein, the Al element has a large different constant of the crystal lattice for the active layer, and hence the conventional problem of stress release is likely to result. The proportion of the In element causes the differences between the crystal lattice structures of the electron blocking combination layer 230 and the active layer 212 to be not so obvious, and can moderate the problem of stress release.

The aforesaid electron blocking combination layer 230 comprises a third AlInGaN layer 242 and a fourth AlInGaN layer 244. The aforesaid third AlInGaN layer 242 has a third thickness, and the aforesaid fourth AlInGaN layer 244 has a fourth thickness. The sum of the third thickness and the fourth thickness is equal to the sum of the first thickness and the second thickness.

The combination epitaxy structure further comprises a fifth AlInGaN layer 252, a sixth AlInGaN layer 254, a seventh AlInGaN layer 262 and an eighth AlInGaN layer 264, where the total thickness of the fifth AlInGaN layer 252 and the sixth AlInGaN layer 254 is preferably equal to the sum of the first thickness and the second thickness. Furthermore, the total thickness of the seventh AlInGaN layer 262 and the eighth AlInGaN layer 264 is preferably equal to the sum of the first thickness and the second thickness.

The aforesaid use of AlInGaN does not limit the application of the prevent invention. The AlInGaN can be replaced by the following materials which also are included in the scope of the present invention: GaN, AIN, InN, AlGaN, InGaN, and AlInN.

One of the advantages of the present invention is that the electron barrier can prevent the overflowing of electrons and rebound the electrons into the quantum wells of the active layer so that the electrons are recombined with holes to release photons. Furthermore, the combination of Group III-V semiconductor layers with various crystal lattice constants has the effect of stress compensation so that stress between the semiconductor layers and the active layer is reduced.

The above-described embodiments of the present invention are intended to be illustrative only. Those skilled in the art may devise numerous alternative embodiments without departing from the scope of the following claims.

What is claimed is:

1. A light emitting device with an electron blocking combination layer, comprising:
a substrate;
a buffer layer on said substrate;
an n-type gallium nitride layer on said buffer layer;
an active layer on said n-type gallium nitride layer;
at least two Group III-V semiconductor layers with different band gaps deposited periodically and repeatedly on said active layer; and
a p-type gallium nitride layer on said at least two Group III-V semiconductor layers.

2. The light emitting device with an electron blocking combination layer of claim 1, wherein the material of said Group III-V semiconductor layers is aluminum indium gallium nitride, gallium nitride, aluminum nitride, indium nitride, aluminum gallium nitride, indium gallium nitride, or aluminum indium nitride.

3. The light emitting device with an electron blocking combination layer of claim 2, wherein the material of said substrate is Al₂O₃, SiC, Si, GaN, AIN, LiAlO₂, LiGaO₂, or ZnO.

4. A light emitting device with an electron blocking combination layer, comprising:
an active layer; and
a combination of epitaxial structures including a first AlₓIn_{y}Ga_{1-x-y}N layer and a second AlᵤInᵥGa₁₋ᵤ₋ᵥN layer, where 0<x≦1, 0≦y<1, x+y≦1, 0≦u<1, 0≦v≦1, and u+v≦1.

5. The light emitting device with electron blocking combination layer of claim 4, wherein x=u and y≠v.

6. The light emitting device with an electron blocking combination layer of claim 4, wherein said first AlₓIn_{y}Ga_{1-x-y}N layer has a first thickness and said second AlᵤInᵥGa₁₋ᵤ₋ᵥN layer has a second thickness.

7. The light emitting device with an electron blocking combination layer of claim 5, wherein said combination of epitaxial structures further comprises a third AlInGaN layer and a fourth AlInGaN layer.

8. The light emitting device with an electron blocking combination layer of claim 7, wherein said third AlInGaN layer has a third thickness and said fourth AlInGaN layer has a fourth thickness, and the sum of said third thickness and said fourth thickness is equal to the sum of said first thickness and said second thickness.

9. The light emitting device with an electron blocking combination layer of claim 7, wherein said combination of epitaxial structures further comprises a fifth AlInGaN layer and a sixth AlInGaN layer.

10. An optoelectronic semiconductor device with an electron blocking combination layer, comprising:
a substrate;
a buffer layer on said substrate;
an n-type gallium nitride layer on said buffer layer;
an active layer on said n-type gallium nitride layer;
at least two Group III-V semiconductor layers with different band gaps deposited periodically and repeatedly on said active layer; and
a p-type gallium nitride layer on said at least two Group III-V semiconductor layers.

11. The optoelectronic semiconductor device with an electron blocking combination layer of claim 10, wherein the material of said Group III-V semiconductor layers is aluminum indium gallium nitride, gallium nitride, aluminum nitride, indium nitride, aluminum gallium nitride, indium gallium nitride, or aluminum indium nitride.

12. The optoelectronic semiconductor device with an electron blocking combination layer of claim 11, wherein the material of said substrate is Al₂O₃, SiC, Si, GaN, AIN, LiAlO₂, LiGaO₂, or ZnO.

13. An optoelectronic semiconductor device with an electron blocking combination layer, comprising:
an active layer; and
a combination of epitaxial structures including a first AlₓIn_{y}Ga_{1-x-y}N layer and a second AlᵤInᵥGa₁₋ᵤ₋ᵥN layer, where 0<x≦1, 0≦y<1, x+y≦1, 0≦u<1, 0≦v≦1, and u+v≦1.

14. The optoelectronic semiconductor device with electron blocking combination layer of claim 13, wherein x=u and y≠v.

15. The optoelectronic semiconductor device with an electron blocking combination layer of claim 13, wherein said first AlₓIn_{y}Ga_{1-x-y}N layer having a first thickness and said second AlᵤInᵥGa₁₋ᵤ₋ᵥN layer having a second thickness.

16. The optoelectronic semiconductor device with an electron blocking combination layer of claim 14, wherein said combination of epitaxial structures further comprises a third AlInGaN layer and a fourth AlInGaN layer.

17. The optoelectronic semiconductor device with an electron blocking combination layer of claim 16, wherein said third AlInGaN layer has a third thickness and said fourth AlInGaN layer has a fourth thickness, and the sum of said third thickness and said fourth thickness is equal to the sum of said first thickness and said second thickness.

18. The optoelectronic semiconductor device with an electron blocking combination layer of claim 16, wherein said combination of epitaxial structures further comprises a fifth AlInGaN layer and a sixth AlInGaN layer.
